(19) United States
(12) Patent Application Publication
(10) Pub. No.: US 2026/0217232 A1
(43) Pub. Date: Jul. 30, 2026

(54) ELECTRONIC CIRCUIT

(71) Applicant: ZF CV SYSTEMS GLOBAL GMBH, Bern (CH)

(72) Inventors: Simon PAUKA, Hannover (DE); Christian LEIBOLD, Hannover (DE)

(73) Assignee: ZF CV SYSTEMS GLOBAL GMBH, Bern (CH)

(21) Appl. No.: 19/148,960

(22) PCT Filed: Jan. 10, 2024
(86) PCT No.: PCT/EP2024/050474

§ 371 Date: Jul. 17, 2025

(30) Foreign Application Priority Data
Jan. 20, 2023 (DE) 10 2023 200 458.5

(51) Int. Cl. B60T 13/68; B60T 13/22; B60T 13/38; H03K 17/08

(52) U.S. Cl. CPC B60T 13/683; B60T 13/686; H03K 17/08; B60T 13/22; B60T 13/385; B60T 2270/402; B60T 2270/406; B60T 2270/413; H03K 2217/0063; H03K 2217/0072

(57) ABSTRACT

An electronic circuit has an electronic control unit, a safety control unit, and an electronic locking unit with a delay unit and with a memory unit. The electronic control unit can control an actuator via a normal-operation control signal in a specified manner. The safety control unit can generate a triggering signal for the electronic locking unit without the electronic control unit influencing generation of the triggering signal. The delay unit can receive the normal-operation control signal and to transmit it with a time delay to the memory unit. The memory unit can receive the triggering signal and store the normal-operation control signal with the time delay upon the memory unit receiving the triggering signal. The electronic locking unit can control the actuator based on the stored normal-operation control signal, upon the memory unit receiving the triggering signal and storing the signal transmitted with the time delay.

### RELATED APPLICATIONS

This application claims the benefit under 35 U.S.C. § 371 as a U.S. National Phase Application of application no. PCT/EP2024/050474, filed on 10 Jan. 2024, which claims the benefit of German Patent Application no. 10 2023 200 458.5 filed on 20 Jan. 2023, the contents of which are hereby incorporated herein by reference in their entireties.

### FIELD OF THE DISCLOSURE

The invention relates to an electronic circuit, in particular for controlling a brake system of a motor vehicle. Further aspects of the present disclosure relate to a brake system with the electronic circuit.

### BACKGROUND

DE 10 2018 104 143 A1 describes a pressure-medium-operated brake system for a vehicle that consists of a towing vehicle with a towing vehicle brake and a trailer vehicle with a trailer brake. The brake system also comprises a holding brake module which is connected to an electronic control unit. The holding brake module comprises a control valve, a redundancy valve and a shuttle valve. The valves can be controlled via electronic switchgear with a self-maintaining function, in such manner that in the event of a brake fault or a failure of the electronic control unit, the most recent fault-free switch setting of the control valve or the redundancy valve is maintained so long as the electronic control unit does not change to an operationally safe rest condition, or the ignition system is not switched off.

### Summary

A purpose of the present invention can be regarded as to ensure a particularly reliable and yet simple fail-safe function for an actuator. The objective is achieved by an electronic circuit and a brake system as disclosed herein. Advantageous embodiments will be apparent in light of the present disclosure.

According to the invention an electronic circuit is proposed, which ensures a secure condition of a function which, in the event of an electronic failure, does not itself adopt a safe state. For that purpose, an electronic signal store is provided as part of a system that enables a function which, in the event of a failure of a control unit, an electronic failure or some other failure, does not on its own adopt a secure state. Particular functions do not adopt a secure state if an electrical failure or power-cut occurs. To solve that problem, the electronic circuit according to the invention can maintain the most recent valid state of the functionalities in order to ensure a safe state if there is a failure of the main control unit of the electronic brake system. The electronic signal store can also be said to be a locking unit and is a separate unit that reacts to input signals from other parts of the system and can ensure a safe state if there is a failure of other control units, since it uses a delay unit and a memory for storing the most recent valid status of the function described. The electronic memory recognizes such a failure (or is alerted thereto by other units such as a ‘watchdog’) and changes the hazardous functionality to a safe condition within a determined time. The fail-safe state is not necessarily the de-energized state, but rather, depends on a most recent valid state (energized/de-energized). Accordingly, the invention provides an additional circuit that maintains the most recent valid state in the event of a fault.

According to the present invention, in particular, an electronic hardware locking system is proposed, which works in a circuit or a system that comprises an electronic control unit which delivers control signals to an actuator and to the hardware locking system. In the event of a fault there can be an interface for triggering the lock. Furthermore, an interface for the external resetting of the lock can be provided. In the event of a fault of the electronic control unit, the actuator is controlled by the electronic hardware locking system. In particular, if the electronic control unit fails the electronic hardware locking system maintains the most recent valid state of a functionality (controlled by an actuator), in order to ensure a safe condition. This is a logic system separate from a main control unit, which receives the control signal from the electronic control unit for the actuator.

In this case the control signal of the electronic control unit to the actuator is first delayed by a delay unit for a certain time. In the event of a fault the delayed signal is stored in the memory unit and used from thereto maintain the most recent valid condition of the actuator, in particular until the memory unit is reset by a main controller or via an external reset interface. The hardware locking system needs only a delay unit and a storage block to maintain the most recent valid condition and to ensure a safer state. In that sense, according to a first aspect of the invention, an electronic circuit is provided. The electronic circuit comprises an electronic control unit, a safety control unit and an electronic locking unit with a delay unit and with a memory unit. The memory unit can in particular be an electronic 1-bit memory unit. The locking unit can in particular be implemented by hardware (“hardware latch” or “HW latch”).

In normal operation the electronic control unit is designed to control at least one actuator by means of a normal-operation control signal in a specified manner. The expression “to control in a specified manner” can for example be understood to mean that the actuator is “energized” by the electronic control unit in accordance with a first alternative, so that the actuator is changed to a fixed condition, or that the actuator is “de-energized” by the electronic control unit in accordance with a second alternative, so that the actuator is changed to the fixed condition. For example, the actuator can be a hydraulic valve or a pneumatic valve, in particular in the form of a directional valve that can be actuated electromagnetically. Such a directional valve can for example be switched to an open condition when the directional valve is energized and prestressed to a closed condition (for example by a spring) when the directional valve is not energized. Alternatively, the directional valve can also be switched to the closed condition when the directional valve is energized and to the open condition when it is not energized. This depends on the intended use of the electromagnetically actuated directional valve. The directional valve can in particular be a redundancy valve of a holding brake module or a motor vehicle. Alternatively, or in addition, the redundancy valve of the holding brake module can control the holding brake function of a trailer (optionally) coupled to the motor vehicle.

The safety control unit is designed to generate a triggering signal for the electronic locking unit without the electronic control unit having any influence on the generation of the triggering signal. Thus, the safety control unit works independently of the electronic control unit and can in particular monitor its proper functionality, for example by way of a so-termed watchdog. For example, if the functionality is compromised because of a fault, the safety control unit can generate the triggering signal.

The delay unit is designed to receive the normal-operation control signal and to send it to the memory unit with a time delay. Thus, the memory unit receives in each case a normal-operation control signal located in the past by the amount of the time delay. The memory unit is designed to receive the triggering signal generated by the safety control unit. Furthermore, the memory unit is designed to store the normal-operation control signal sent with its time delay, as soon as the memory unit receives the triggering signal. The electronic locking unit is designed to control the actuator on the basis of the stored normal-operation control signal as an output signal of the memory unit as soon as the memory unit has received the triggering signal and the normal-operation control signal sent with a time delay.

Instead of monitoring the control signal on the low side (ground) to the at least one actuator, in particular to a number of valves, a PIN on the positive side (supply) of the actuator can be monitored. The low-side connection (ground) to an actor is often used in order to enable PWM (Pulse Width Modulation) control, which prevents overheating of the actor since it reduces the heat energy generated. However, a PWM signal does not provide a reliable static control signal (and is therefore not a valid input for the hardware locking unit), since in the active condition it consists of alternating high and low phases. To solve that problem, it is proposed to connect the hardware locking unit to a high-side (supply) of the actuator which is not PWM-controlled, so that a low-side of the actuator can be used for PWM control. In this sense, according to a further embodiment it is provided that the electronic control unit is designed (in normal operation, in particular when no fault is present) to control a high-side switch of the actuator by means of the normal-operation control signal in the specified manner. If there is a fault the high-side switch of the actuator can be activated, for example by the safety control unit. In this case the memory unit of the locking unit can be designed (if there is a fault) to control a low-side switch by means of the stored normal-operation control signal. In turn the electronic control unit (particularly during normal operation when there is no fault) can be designed to control the low-side switch of the actuator by pulse width modulation.

A high-side switch can in particular be understood to be a transistor which, depending on its switch position, connects or disconnects a supply rail with high voltage (typically 24 volts in an industrial application) to or from a load. If the actuator is a directional valve that can be actuated electromagnetically, then the high-side switch can in particular be designed to connect a magnetic circuit of the directional valve to the positive pole of an electrical energy store when the high-side switch is in a closed condition, and to disconnect the magnetic circuit of the directional valve from the positive pole of the electrical energy store when the high-side switch is in an open condition. Alternatively or in addition, the high-side switch can in particular be designed to connect the magnetic circuit of the directional valve to an output terminal of an ignition switch arranged behind the positive pole of an electrical energy store when the high-side switch is in a closed switch position, and to disconnect the magnetic circuit of the directional valve from that of the connection terminal of the ignition switch when the high-side switch is in an open switch position.

A low-side switch can in particular be understood to mean a switch which, depending on its switch position, connects or disconnects an electric load by switching over the ground-side (low-side) of a load supply. If the actuator is a directional valve that can be actuated electromagnetically, then the low-side switch can in particular be designed to connect a magnetic circuit of the directional valve to ground (“to earth it”) when the low-side switch is in a closed switch position, and to disconnect the magnetic circuit of the directional valve from ground when the low-side switch is in an open switch position.

So far as the triggering signal is concerned, the safety control unit can be designed to generate a status signal which adopts either a normal-operation value (“1”) or a fault value (“0”). The normal-operation value (“1”) shows that the actuator is being controlled in the specified manner. In contrast, the fault value (“0”) shows that the actuator is not being controlled in the specified manner. If the value of the status signal changes from the normal-operation value (“1”) to the fault value (“0”), then, illustrated graphically in the time variation, this results in a falling flank (from “1” to “0”). In such a case the memory unit can be locked in order to maintain a safe condition of the actuator, since by inverting the fault signal (“0”) a rising flank (from “O” to “1”) is produced in the time variation. Thus, this inverted fault signal (“1”) serves as the triggering signal. In this case the memory unit remembers the logical status (“1”) of the normal-operation control signal, which is in the past owing to the time-delayed transmission by the delay unit, for example 25 milliseconds in the past. In that sense, in an embodiment it is provided that the safety control unit comprises an inverter and the inverter is designed to change the fault value to the normal-operation value and to transmit that normal-operation value as the triggering signal to the memory unit. In general, when triggering takes place the memory unit stores the output value of the delay unit at the time-point concerned, which corresponds to the most recent valid condition of the normal-operation signal before the occurrence of the fault value (“0”) (the so-termed Last Known Valid State). The delay time is suitably chosen such that the signal of the delay unit reliably reproduces the state before the occurrence of the fault.

The locking unit can be deactivated, in particular, externally. The memory unit can be reset when the memory unit receives a reset signal. The resetting of the memory unit includes in particular that the output signal of the memory unit adopts a transfer value. In this case the locking unit surrenders the control of the actuator again to the electronic control unit. In that sense, in a further embodiment it is provided that the memory unit is designed to receive the reset signal, whereas the locking unit is designed to control the actuator by means of the stored normal-operation control signal only until the memory unit receives the reset signal. Thereafter, the locking unit stops controlling the actuator. The electronic control unit is then designed to take over control of the actuator again as soon as the memory unit receives the reset signal.

The electronic locking system can be reset by way of an external interface (reset unit) or, for example, by switching off the power supply. Other methods for external deactivation are also conceivable, for example by an external switch with fixed wiring. According to a further embodiment it can be provided that the reset signal is generated by a reset unit separate from the locking unit. Thus, the external “reset unit” can operate in addition or alternatively to the usual reset methods. Furthermore, the reset unit can act at any point in the locking unit, for example by means of a separate input on the memory unit or with a separate logic block. The carrying out of a reset by switching off the power supply has the result that the locking unit adopts a defined state (in this case the value “0”). Thereby, for example, the redundancy logic is also set to a defined state. This represents the added value or a function extension compared with the “reset unit”.

The safety control unit with its inverter can for example be regarded as a reset unit. The memory unit, in particular in the form of a 1-bit memory, can in particular then be reset when the status signal generated by the safety control unit adopts the normal-operation value (“1”) at any time, i.e., when the electronic control unit is again capable of controlling the actuator in the specified manner. By the inverter, the normal-operation value is then inverted to the fault value. In that sense, according to a further embodiment it is provided that the inverter is designed to change the normal-operation value (“1”) to the fault value (“0”) and to transmit that fault value (“0”) as the reset signal to the memory unit.

When the status signal generated by the safety control unit has the fault value (“0”), then this fault value (“0”) can indicate that the actuator is not (yet) controlled by the electronic control unit in the specified manner because the electronic control unit is starting up or is in a starting phase. In that case the electronic control unit can read the status of the locking unit since the electronic control unit measures analog return-messages of the high-side switch and the low-side switch of the actuator. Basically, measurement of various signals is also conceivable in order to draw a conclusion about the status of the locking unit. As examples and thus not exclusively, the first or second failsafe control signal, a selected failsafe signal or an output signal to the low-side switch can be mentioned here. In that way the electronic control unit can recognize the status of the locking unit and maintain that status after the end of the starting process. In that sense, according to a further embodiment it is provided that the fault value (“0”) indicates that the actuator is not being controlled by the electronic control unit in the specified manner by way of the normal-operation control signal, because the electronic control unit is in a start-up phase. In that case the electronic control unit is designed to measure analog return-messages from the high-side switch and the low-side switch of the actuator, and, as a function thereof, to infer an operating condition of the locking unit. This takes place while the electronic control unit is in the start-up phase and when the safety control unit has generated the control signal in such manner that it adopts the fault value (“0”). Furthermore, the electronic control unit is designed to control the actuator on the basis of the measured analog return-messages, in such manner that the locking unit maintains its operating condition after the electronic control unit has completed the starting phase. Basically, the operating condition of the locking unit can be changed after the end of the start-up phase by the reset signal. Functionally, it is then ensured that the operating condition of the actuator is taken over or maintained.

The safety control unit can in particular comprise a ‘watchdog’ which is connected on the input side to the electronic control unit and on the output side to the inverter. Thus, the watchdog can on the one hand monitor the correct functioning of the electronic control unit and on the other hand it can generate the appropriate control signal which is inverted by the inverter as described earlier.

According to a further embodiment, the delay unit is designed to transmit the normal-operation control signal to the memory unit with a time delay of at least 25 milliseconds. In particular, the time delay of 25 milliseconds represents a time period that begins when the delay unit receives the normal-operation signal and ends when the delay unit transmits the normal-operation signal to the memory unit. The signal at an input of the delay unit is delayed by at least 25 milliseconds before being emitted via an output of the delay unit. During this delay, a logical value or other property of the input signal is not changed. The delay can vary as a function of the temperature. The implementation of the delay unit can in particular comprise an RC low-pass filter and two sequential Schmitt-trigger inverters.

According to a second aspect of the invention, a brake system for a motor vehicle is provided. The brake system comprises an electronically controlled holding brake module with a first directional valve in the form of a control valve, with a second directional valve in the form of a redundancy valve and with a pressure-controlled shuttle valve. The brake system also comprises an electronic circuit according to the first aspect of the invention.

The brake system is characterized in particular by the following:
the electronic control unit of the electronic circuit is designed to control the redundancy valve as an actuator by means of a normal-operation control signal in a specified manner,
the safety control unit of the electronic circuit is designed to generate a triggering signal for the electronic locking unit, without the electronic control unit influencing the generation of the triggering signal,
the delay unit of the locking unit of the electronic circuit is designed:
to receive the normal-operation control signal, and
to transmit the normal-operation control signal, with the time delay, to the memory unit of the electronic circuit of the locking unit,
the memory unit is designed:
to receive the triggering signal generated by the safety control unit,
to store the normal-operation control signal transmitted, with the time delay, as soon as the memory unit receives the triggering signal,
and
the electronic locking unit of the electronic circuit is designed to control the redundancy valve by means of the stored normal-operation control signal as the output signal of the memory unit, as soon as the memory unit has received the output signal and has stored the normal-operation control signal.

To increase the redundancy, the electronic circuit can in addition comprise a further delay unit and a further memory unit, such that:
the electronic control unit is designed to control the control valve as a further actuator by means of a further normal-operation control signal in a specified manner,
the further delay unit is designed:
to transmit the further normal-operation control signal, with the time delay, to the further memory unit,
the further memory unit is designed:
to receive the triggering signal generated by the safety control unit,
to store the further normal-operation control signal transmitted by the further delay unit, with the time delay, as soon as the memory unit receives the triggering signal,
and
the electronic delay unit is designed to control the control valve by means of the stored further normal-operation control signal as the output signal of the further memory unit, as soon as the further memory unit has received the triggering signal and has stored the further normal-operation control signal.

The embodiments described above in connection with the electronic circuit, whose technical effects and associated advantages also apply to the brake system according to the second aspect of the invention, emerge in particular from the figure descriptions given in what follows.

### BRIEF DESCRIPTION OF THE DRAWINGS

Thus, in what follows, embodiments of the invention are explained in greater detail with reference to the schematic drawings, in which the same or similar elements are denoted by the same indexes, and which show:

FIG. 1: A view from above, of part of a brake system for a motor vehicle and a trailer vehicle,

FIG. 2: Details of an example embodiment of an electronic circuit according to the invention, for the brake system according to FIG. 1,

FIG. 3: Examples of signal flows of the electronic circuit shown in FIG. 2,

FIG. 4: A switching scheme of a power supply unit of an electronic control unit of the brake system shown in FIG. 1,

FIG. 5: A power supply of a redundancy logic and an electronic locking unit of the electronic circuit shown in FIG. 2, and

FIG. 6: A further example embodiment of an electronic circuit according to the invention for the brake system shown in FIG. 1.

### DETAILED DESCRIPTION

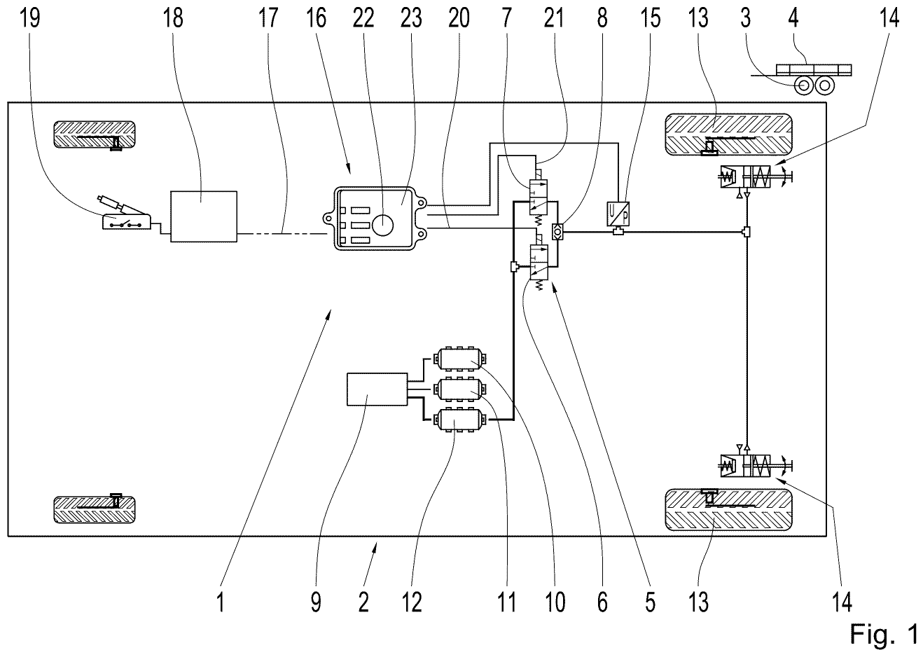

FIG. 1 shows part of a brake system 1 for a motor vehicle 2, no more of which is shown. The motor vehicle 2 is for example an agricultural utility vehicle, in particular a tractor. The brake system 1 fulfills in particular a holding or braking function of wheels 13 of the motor vehicle 2 and of the trailer brake 3 of the trailer vehicle 4, which is only indicated in FIG. 1. The functions described in greater detail in what follows are part of a tractor brake system platform, the so-termed EBP platform. The EBP platform is intended to ensure the safe operation of the brake system 1 in a variety of failure scenarios.

The brake system 1 comprises an electronically controlled holding brake module 5. In turn, the holding brake module 5 comprises a first directional valve in the form of a control valve 6, a second directional valve in the form of a redundancy valve 7, and a pressure-controlled shuttle valve 8. On its input side the holding brake module 5 is supplied with compressed air from a compressed-air source 9. The compressed-air source 9 comprises a first compressed-air tank 10, a second compressed-air tank 11 and a third compressed-air tank 12. In the example embodiment shown, the control valve 6 and the redundancy valve 7 are each connected on the input side to the third compressed-air tank 12 of the compressed-air supply source 9, although this is purely an example. A valve slide of the control valve 6 and a valve slide of the redundancy valve 7 are each prestressed by a spring to a closed state in which the pressure from the compressed-air source 9 does not pass through the control valve 6 and the redundancy valve 7 (“normally closed”). The valve slide or valve slides could each also be replaced by a valve seat such that the valve seat can be closed or opened, for example, by a tappet moved by magnetic force. Alternative actuation modes of the moving tappet, for example by means of levers, are also conceivable.

On the output side the control valve 6 and the redundancy valve 7 are each connected to the shuttle valve 8, so that the respective higher pressure of the two valves 6, 7 is delivered by the shuttle valve 8 in order to supply pressure to two spring-loaded holding brake valves 14 each associated with a wheel 13 and the trailer brake 3. If the control valve 6 fails, the pressure of the redundancy valve 7 can be used further, provided that the redundancy valve 7 has not failed. If the redundancy valve 7 fails, then the pressure of the control valve 6 can be used further, provided that the control valve 6 has not failed. A pressure sensor 15 measures the pressure delivered by the shuttle valve 8 and transmits the measured pressure to an electronic control unit 16 of the brake system 1.

When at least one of the valve slides of the two valves 6, 7 is in its open shift position, then a predetermined pressure can be passed through the control valve 6 and/or the redundancy valve 7 and delivered via the shuttle valve 8. The spring-loaded holding brake valve 14 and the trailer brake 3 are then actuated in such manner that the holding brake is released against the prestressing by the spring. The wheels of the motor vehicle 2 and/or the trailer vehicle 4 are then not immobilized. In contrast, when both valve slides of the two valves 6, 7 are in their closed shift position, then no pressure passes through the control valve 6 and the redundancy valve 7 to be delivered by the shuttle valve 8. The spring-loaded holding brake valves 14 and the trailer brake 3 then are not actuated as described above, but instead are activated. The wheels 13 of the motor vehicle 2 and/or those of the trailer vehicle 4 are then immobilized. In this connection it can be said that the electronically controlled holding brake module 5 has an inverted shift characteristic. Thus, the holding brake of the motor vehicle 2 and the trailer brake 3 are, for example, actuated when no pressure is delivered by the shuttle valve 8, and released when a sufficiently high pressure is delivered by the shuttle valve 8. Sometimes the trailer brake can be made without a spring. Accordingly, actuation then takes place by means of a further valve, for example a so-termed trailer control valve, which again inverts the signal coming from the shuttle valve 8 and so delivers pressure from the compressed-air tank to the trailer brakes 3. In other words, in the last-mentioned embodiment the trailer brake 3 is not actuated by a spring but by way of the service brake of the trailer.

The electronic control unit 16 of the brake system 1 is connected via a CAN bus 17 to an electronic (main) control unit 18 of the motor vehicle 2. In the example embodiment illustrated the electronic (main) control unit 18 of the motor vehicle 2 is connected in particular to a man-machine interface 19. By way of the man-machine interface 19 a driver or user of the motor vehicle 2 can operate the two holding brake valves 14 of the motor vehicle 2 and/or the trailer brake 3 of the trailer vehicle 4.

In particular, the pressure supply to the holding brake valves 14 and the trailer brake 3 should be prevented from failing and the wheels of the motor vehicle 2 or the trailer vehicle 4 from being immobilized while the motor vehicle 2 and the trailer vehicle 4 are being driven. During normal operation of the brake system 1 this pressure supply function is controlled by the electronic control unit 16 of the brake system 1. For that purpose, the electronic control unit 16 of the brake system 1 is connected by a first electronic control line 20 to the control valve 6 and by a second electronic control line 21 to the redundancy valve 7. When the electronic control unit 16 of the brake system 1 energizes the control valve 6 and the redundancy valve 7 via the electronic control lines 20, 21, then the valve slides of the control valve 6 and the redundancy valve 7 are moved against the spring prestress to their open shift positions. In the open shift position, the pressure passes from the compressed-air supply 9 through the control valve 6 and the redundancy valve 7. Whichever is the higher of the two pressures passes via the shuttle valve 8 to the holding brake valves 14 and/or to the trailer brake 3 for their pressurization, so that the wheels of the motor vehicle 2 and/or the trailer vehicle 4 are not immobilized.

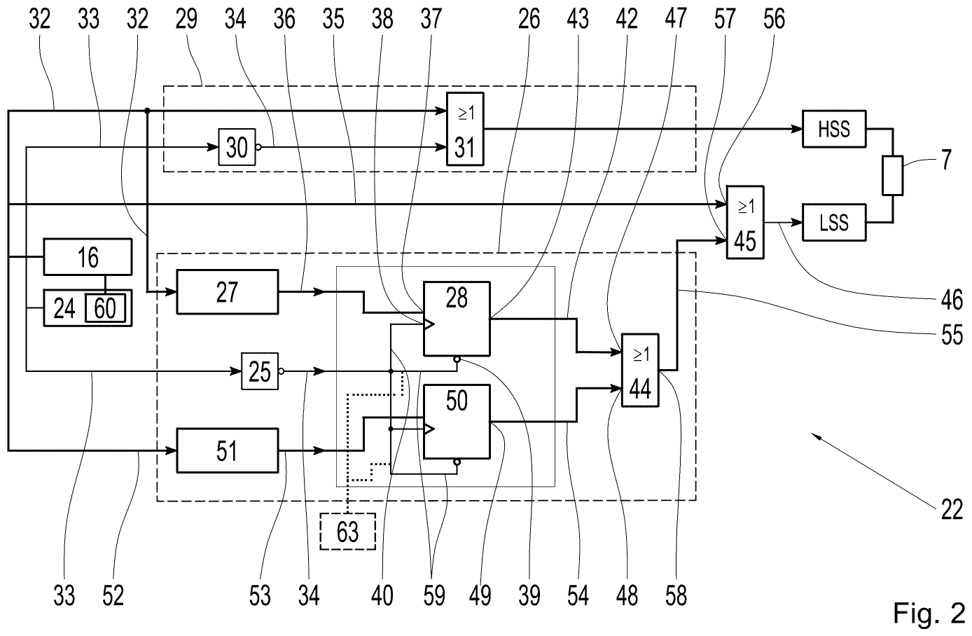

However, if the electronic control unit 16 of the brake system 1 is not functioning properly during driving operation, then its function is controlled by a electronic circuit 22 described in greater detail below, which in the example embodiment shown in FIG. 1 is accommodated in a common housing 23 of the electronic control unit 16 of the brake system 1. As shown in FIG. 2, the electronic circuit 22 comprises the electronic control unit 16 of the brake system 1, a safety control unit 24 with an inverter 25 and a watchdog 26. In addition, the electronic circuit 22 comprises an electronic locking unit 26 with a first electronic delay unit 27 and a first memory unit 28, which latter is in the form of a 1-bit memory unit. Furthermore, the electronic circuit 22 comprises a redundancy logic system 29 for the redundancy valve 7. In turn, the redundancy logic system 29 for the redundancy valve 7 comprises a further inverter 30 and a first OR-gate 31. Apart from that a high-side switch HSS and a low-side switch LSS are connected to the redundancy valve 7.

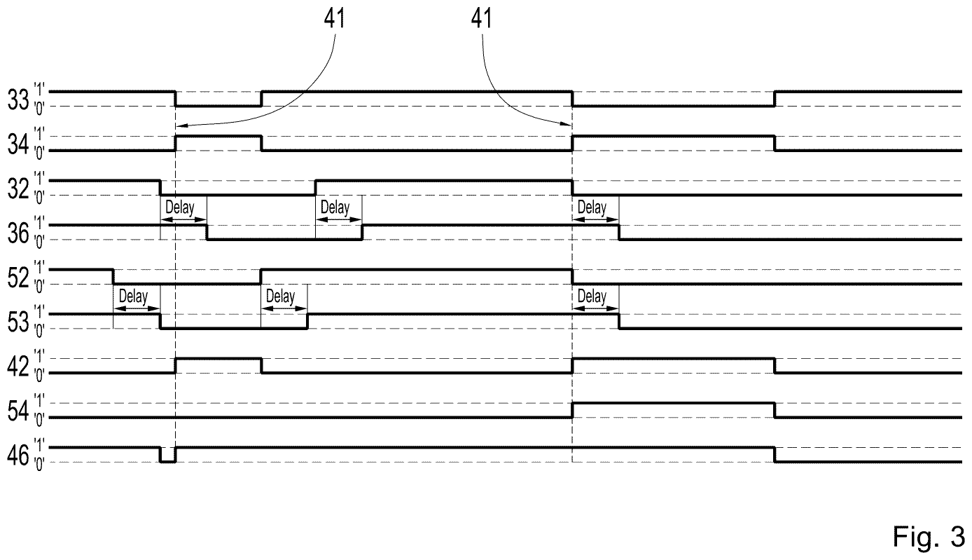

In the normal-operation condition the electronic control unit 16 of the brake system 1 generates a first normal-operation control signal 32 for the high-side switch. By means of the normal-operation control signal 32 the electronic control unit 16 of the brake system 1 can activate and deactivate the high-side switch HSS so that, in the manner described above, the valve slide of the redundancy valve 7 is moved to its open shift position (when the HSS is activated or closed and at the same time the low-side switch LSS is also activated), or to its closed shift position (when the high-side switch HSS is deactivated or open). In this connection it can be said that the electronic control unit 16 is designed to control the redundancy valve 7 by means of the first normal-operation control signal 32 in a specified manner. Owing to the nature of the FSC-AC concept applied in the present case, the first normal-operation control signal 32 is a direct-current (DC) signal. In the signal variation shown as an example in FIG. 3, the first normal-operation control signal 32 adopts the value “1” when the electronic control unit 16 of the brake system 1 energizes the high-side switch HSS and therefore activates or closes it. On the other hand, the first normal-operation control signal 32 adopts the value “0” when the electronic control unit 16 of the brake system 1 does not energize the high-side switch HSS and so deactivates or opens it. The electronic control unit 16 of the brake system 1 transmits the first normal-operation control signal 32 as an input signal to the first OR gate 31 of the redundancy logic system 29. In a similar manner, the electronic control unit 16 of the brake system 1 can also control the control valve 6 by way of its high-side switch (not shown in FIG. 2).

Furthermore, in its normal-operation condition the electronic control unit 16 of the brake system 1 generates a second normal-operation control signal 35 for the low-side switch LSS of the redundancy valve 7. By means of the second normal-operation control signal 35 the electronic control unit 16 of the brake system 1 can activate and deactivate the low-side switch LSS, so that in the manner described above the valve slide of the redundancy valve 7 is moved to its open shift position (when the low-side switch LSS is in its activated or closed shift position and at the same time the high-side switch HSS is closed), or to its closed shift position (when the high-side switch LSS is deactivated or open). In this case the redundancy valve 7 can be actuated by means of a direct-current signal or by means of pulse-width modulation (PWM), because that signal can be an input signal for the locking unit 26 described in greater detail later on.

The safety control unit 24 works independently of the electronic control unit 16 of the brake system 1. The watchdog 60 of the safety control unit 24 monitors the function of the electronic control unit 16 of the brake system 1. In the example embodiment illustrated, the safety control unit 24 can emit a binary status signal 33 on the basis of the result of the monitoring of the electronic control unit 16 of the brake system 1 by the watchdog 60. In this case a normal-operation value “1” of the status signal indicates that the electronic control unit 16 of the brake system 1 is functioning properly, so that the safety control unit 24 can conclude that the redundancy valve 7 is being controlled in the specified manner. In contrast, a fault value “0” of the status signal indicates that at least one of the following faults exists, namely that the electronic control unit 16 of the brake system 1 is not functioning properly, that the electronic control unit 16 of the brake system 1 is in a starting phase, that the safety control unit 24 is not functioning properly, or that the safety control unit 24 is in an initialization or starting phase. If at least one of these fault situations exists, then the safety control unit 24 can conclude that the redundancy valve 7 is not being controlled in the specified manner.

The safety control unit 24 transmits the status signal 33 generated to the further inverter 30 of the redundancy logic system 29. The further inverter 30 of the redundancy logic system 29 converts the status signal 33 transmitted by the safety control unit 24 to the further inverter 30 of the redundancy logic system 29 into an inverted status signal 34. If the status signal 33 transmitted by the safety control unit 24 to the further inverter 30 of the redundancy logic system 29 has the normal-operation value “1”, then the further inverter 30 converts the status signal 33 in such manner that the inverted status signal 34 adopts the fault value “0” and transmits the inverted status signal 34 with the fault value “O” as an input signal to the first OR-gate 31 of the redundancy logic system 29. In contrast, if the status signal 33 transmitted by the safety control unit 24 to the further inverter 30 of the redundancy logic system 29 has the fault value “0”, then the further inverter 30 converts the status signal 33 in such manner that the inverted status signal 34 adopts the normal-operation value “1” and transmits the inverted status signal 34 with the normal-operation value “1” as an input signal to the first OR-gate 31 of the redundancy logic system 29.

The first OR-gate 31 of the redundancy logic system 29 thus receives two input signals, namely the first normal-operation control signal 32 (from the electronic control unit 16 of the brake system 1) and the inverted status signal 34 (from the further inverter 30 of the redundancy logic system 29). The first OR-gate 31 is designed to output whichever of the two said input values 32, 34 has a value equal to or greater than 1. If none of the above-mentioned fault cases exists, then the status signal 33 adopts the value “1” and the inverted status signal the value “0”. In that case the first normal-operation control signal adopts the value “1”, because the electronic control unit 16 of the brake system 1 energizes the high-side switch HSS and so activates or closes it. It should be noted, however, that the normal-operation control signal 32 can even have the value “0” when no fault is present, for example if the actuator should not be energized. For example, that would be the case when a parking brake is engaged or activated. Thus, in that case the first OR-gate 31 outputs the first normal-operation control signal 32 with the value “1” in order to control the high-side switch HSS of the redundancy valve 7. On the other hand, if at least one of the aforementioned exists, then the status signal 33 adopts the value “0” and the inverted status signal 34 becomes “1”. In such a case the first normal-operation control signal 32 becomes “0”, for example if the electronic control unit 16 of the brake system 1 develops a fault and does not energize the high-side switch HSS in the required manner and does not energize or close it. Thus, in that case the first OR-gate 31 emits the inverted status signal 34 with the value “1” in order control the high-side switch HSS of the redundancy valve 7. In that way the redundancy logic system 29 ensures that the high-side switch HSS of the redundancy valve 7 is always activated when the safety control unit 24 triggers a failsafe condition of the electronic control unit 16.

The electronic control unit 16 of the brake system 1 transmits the first normal-operation control signal 32 as an input signal to the first delay unit 27. With a time delay of at least 25 milliseconds (indicated in FIG. 3 by “Delay” in the corresponding signal variations), the first delay unit 27 emits the first normal-operation control signal 32 as an output signal 36 and transmits that output signal 36 as a signal input 37 to the first memory unit 28. The logic level (“1” or “0”) or some other properties of the first normal-operation control signal 32 are not changed during this. The time delay can vary as a function of the temperature. The implementation of the first delay unit 27 can in particular comprise an RC low-pass filter and two sequential Schmitt trigger inverters (not shown).

The safety control unit 24 transmits the status signal 33 generated to the inverter 25 of the safety control unit 24. The inverter 25 of the safety control unit 24 converts the status signal 33 received from the safety control unit 24 (like the inverter 30 of the redundancy logic system 29) into an inverted status signal 34. If the status signal 33 transmitted by the safety control unit 24 to its inverter 25 has the normal-operation value “1”, then the inverter 25 converts the status signal 33 in such manner that the inverted status signal 34 has the fault value “0” and transmits this inverted status signal 34 with the value “0” to a trigger connection 38 and a reset connection 39 of the first memory unit 28. If the status signal 33 transmitted by the safety control unit 24 to its inverter has the fault value “0”, then the inverter 25 changes the status signal 33 in such manner that the inverted status signal 34 has the normal-operation value “1” and transmits the inverted status signal 34 with the normal-operation value “1” to the trigger connection 38 and to the reset connection 39 of the first memory unit 28.

The inverted status signal 34 generated by the inverter 25 of the safety control unit 24, with the value “1”, serves the first memory unit 28 as a triggering signal 40 which the safety control unit 24 has generated, without the electronic control unit 16 of the brake system 1 having had any influence on the generation of the triggering signal 40. When the first memory unit 28 receives the triggering signal 40 generated by the safety control unit 24, then the triggering signal 40 causes the memory unit 28 to store the normal-operation control signal 36 transmitted by the delay unit 27 with the time delay. This triggering takes place exactly when the inverted status signal 34 changes its value from “0” to “1”. In the time variation shown in FIG. 3 this is represented by two rising flanks 41 of the inverted status signal 34, whereby in each case a failsafe state is triggered by the safety control unit 24.

The first memory unit 28 emits the stored normal-operation control signal 36 delayed by at least 25 milliseconds as a first failsafe control signal 42. The first failsafe control signal 42 is a normal-operation control signal 36 from the past, namely a normal-operation control signal 36 which lags by at least 25 milliseconds. In each case that time-point is before the rising flanks in FIG. 3. At that time-point neither of the above-described cases existed and the redundancy valve 7 was being controlled is the specified manner by the electronic control unit 16 of the brake system 1 by means of the normal-operation control signal 36.

The first memory unit 28 can output the first failsafe control signal 42 via a signal output 43 of the first memory unit 28, and transmit it as an output signal 46 via a second OR-gate 44 and via a third OR-gate 45 to the low-side switch LSS of the redundancy valve 7, in order to control the low-side switch in such manner that the redundancy valve 7 maintains its condition before the onset of the fault at the rising flank 41. In the present case this is the condition in which the low-side switch LSS is activated or closed, so that the redundancy valve 7 is energized and its valve slide moves to the open shift position. In this way therefore, the electronic delay unit 26 controls the redundancy valve 7 on the basis of the stored normal-operation control signal 36 as the first output signal 42 of the first memory unit 28, as soon as the first memory unit 28 has received the triggering signal 40 and has stored the time-delayed normal-operation control signal 36 transmitted to it.

FIG. 3 shows that the value of the normal-operation control signal 32 falls from “1” to “0” when a fault is present. The watchdog of the safety control unit 24 recognizes this fault a few milliseconds later. Thereby, the rising flank 41 of the inverted status signal 34 also only occurs a few milliseconds after the onset of the fault, but that is not critical. This period a few milliseconds long between the occurrence of the fault and the rising flank 41 of the inverted status signal 34 is, firstly, much shorter than the delay with which the normal-operation control signal 32 is transmitted by the delay unit 27 to the memory unit 28. Secondly, the period lasting a few milliseconds between the onset of the fault and the rising flank 41 of the inverted status signal 34 is not long enough for the holding brake of the motor vehicle 2 or the trailer brake to be able to be actuated. For that to happen, a period of the order of 100 milliseconds or even much longer would be needed.

The second OR-gate 44 has a first input 47 and a second input 48. The first input 47 of the second OR-gate 44 is connected to the output of the first memory unit 28. The second input 48 of the second OR-gate 44 is connected to an output 49 of a second memory unit 50 of the locking unit 26. In the example embodiment illustrated the second memory unit 50 is made identically to the first memory unit 28. The second memory unit 50 collaborates with a second delay unit 51 of the locking unit 26 and the safety control unit 24 in the same way as do the first delay unit 26 and the first memory unit 28. In the example embodiment illustrated the second delay unit 51 is made identically to the first delay unit 27.

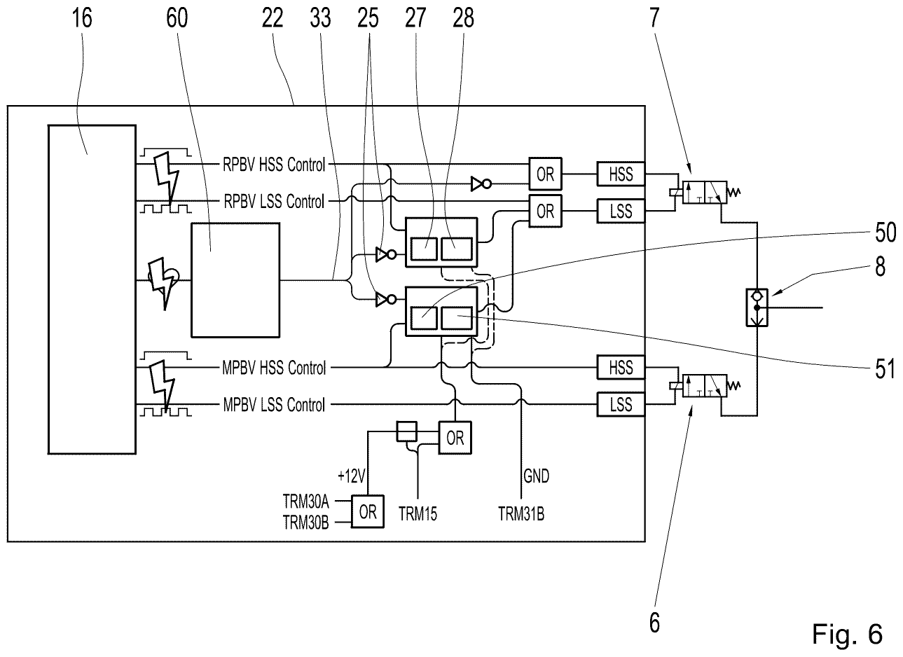

The functional difference lies only in the signal inputs and signal outputs, in particular the input signal for the second delay unit 51, as described in greater detail in what follows. Thus, in the normal-operation condition of the brake system 1 the electronic control unit 16 generates—in a similar way as for the high-side switch HSS of the redundancy valve 7—a third normal-operation control signal 52 for a high-side switch (not shown in FIG. 2, see FIG. 6) of the control valve 6. This third normal-operation control signal 52 is transmitted by the second delay unit 51 to the second memory unit 50, with a time delay of at least 25 milliseconds as a time-delayed second normal-operation control signal 53.

The safety control unit 24 monitors the electronic control unit 16 of the brake system 1, concludes on the basis of that monitoring—as described above in connection with the control of the redundancy valve 7—whether or not the control valve 6 is being controlled in the specified manner, and emits the corresponding status signal 33, which is inverted by the inverter 25. The second memory unit 50 can store the time-delayed second normal-operation control signal 53 and output it as a second failsafe control signal 54, in a similar way to that described above in connection with the first memory unit 28.

The second failsafe control signal 54 is applied to the second input 48 of the second OR-gate 44 and the first failsafe control signal 42 (as already described earlier) to the first input 47 of the second OR-gate 44. The second OR-gate emits whichever of the two failsafe control signals 42, 54, as the failsafe control signal 55 of choice, has a value greater than or equal to 1. The third OR-gate has a first input 56 and a second input 57. The first input 56 of the third OR-gate 45 is connected to the electronic control unit 16 of the brake system 1 and receives the second normal-operation control signal 35 for the low-side switch LSS of the redundancy valve 7. The second input 57 of the third OR-gate 45 is connected to an output 58 of the second OR-gate 44 and receives the chosen failsafe control signal 55. The third OR-gate 45 emits whichever of the two control signals 35, 55, as an output signal 46 to the low-side switch LSS of the redundancy valve 7, has a value greater than or equal to 1.

The two memory units 28 and 50 are reset when the memory units 28, 50 receive a reset signal 59. In the example embodiment illustrated the reset signal 59 is generated by the safety control unit 24. In this case the inverter 25 of the locking unit 26 converts a normal-operation value “1” received into the fault value “0” and transmits this fault value “0” as the reset signal 59 to the memory units 28, 50. In such a case the output value of the two memory units 28, 50 is reset to a transfer value (“default”) that corresponds to the value “0”. In that case the locking unit 26 hands over the control of the redundancy valve 7 and the control valve 6 to the electronic control unit 16. Alternatively, the reset signal 59 can be generated by a reset unit 63 separate from the locking unit 26, as indicated in FIG. 2 by dotted lines. The external reset unit 63 can for example be designed to reset the memory unit 28 of the locking unit 26 by switching off the power supply. The external reset unit 63 can also be implemented by an external hard-wired switch, by means of which the power supply in particular of the two memory units 28, 50 is switched off for the reset process and can be switched on again to resume operation. Alternatively, or in addition to the reset process initiated by means of the external reset unit 63, as already described earlier, that process can be brought about by the methods mentioned above.

When the status signal generated by the safety control unit 24 has the fault value “0”, then that fault value “0” can for example represent the fact that the redundancy valve 7 is therefore not yet being controlled by the electronic control unit 16 in the specified manner by virtue of the first normal-operation control signal 32 because the electronic control unit 16 is starting up or in a starting phase. In that case the electronic control unit 16 can read out the status of the locking unit 26 since the electronic control unit 16 measures analog return-messages of the high-side switch HSS and the low-side switch LSS of the redundancy valve 7. In that way the electronic control unit 16 can recognize the status of the locking unit 26 and maintain its status after the end of the starting process of the electronic control unit 16 of the brake system 1.

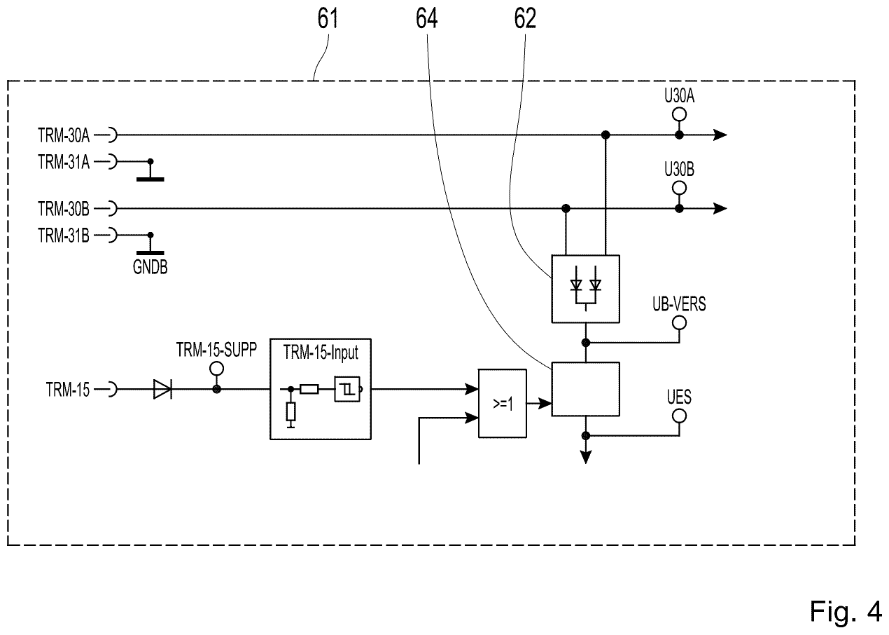

FIG. 4 shows a power supply unit 61 of the electronic control unit 16 of the brake system 1. The power supply unit 61 provides the electronic control unit 16 of the brake system 1 with two independent power supply terminals TRM-30A, TRM-30B, each of them connected to a separate ground TRM-31A-GND and TRM-31B-GNDB. The two power supplies TRM-30A and TRM-30B are merged via a passive reverse polarity protection unit 62 in UB-VERS. Each terminal TRM-30A, TRM-30B also supplies a plurality of valves. The details of the valve power supply are not shown in FIG. 4. In order to activate the computer system and all the other internal circuits, a wake-up signal is needed. The electronic control unit 16 of the brake system 1 can be activated via a vehicle ignition input TRM-15 of a vehicle ignition power supply TRM-15-SUPP. The corresponding input circuit TRM-15-Input delivers a release signal for a limiting unit (“limiter”). The limiter 64 protects a downstream circuit from overvoltage and at the same time functions as a gate. When the limiter 64 is released, the electronic control unit 18 of the motor vehicle 2 is activated. When the electronic control unit 18 of the motor vehicle 2 has started up completely, the electronic control unit 16 of the brake system 1 can be kept activated by a self-hold signal, even if the release signal of the input circuit TRM-15-Input has been discontinued. This is necessary in order to carry out a proper switching-off process when the vehicle ignition TRM-15 is switched off. When the limiter 64 is activated the voltage, known as the UES, is equal to UB-VERS except in overvoltage situations.

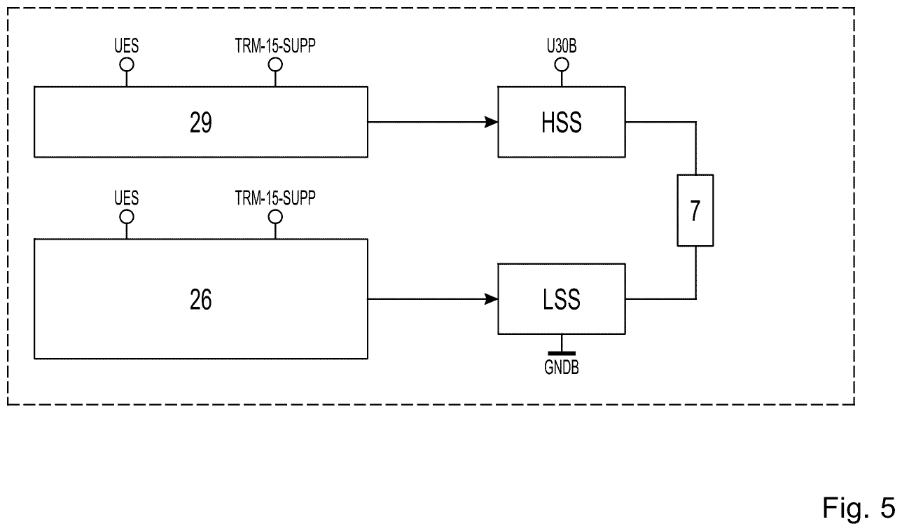

FIG. 5 shows that the internal circuits of the redundancy logic system 29 and the locking unit 26 are each supplied by the voltage UES and the input voltage of the vehicle ignition supply TRM-15-SUPP. At least one of the voltages must be present so that the redundant parking brake function remains available. The redundancy valve 7 itself is supplied from the independent power supply terminal TRM-30B which is referenced to the ground TRM-31B-GNDB. The redundant parking brake function is not available if both of the supply voltages (UES and TRM-15-SUPP) are not present. This is the case if there is a fault in the computer system such that the self-hold signal is not present and the vehicle ignition supply TRM-15-SUPP is switched off. In that case the internal circuits of the redundancy logic system 29 and the locking unit 26 are no longer energized and can no longer perform any function. Safety regulations may also require the driver of the motor vehicle 2 to be able at any time to actuate or apply the parking brake from his seat. In the event of a fault this is made possible by switching off the vehicle ignition TRM-15, as shown in FIG. 6. The parking brake is actuated if, in the event of a fault, the vehicle ignition TRM-15 is switched off. Then the locking units 26 and 29 are no longer energized, which means that the control and redundancy valves 6, 7 are de-energized and therefore closed. Thereby the control and redundancy valves 6, 7 no longer deliver any pressure, so that the parking brake is actuated.

### INDEXES

Delay Time delay
HSS High-side switch
Limiter Limiting unit
LSS Low-side switch
TRM-15 Vehicle ignition input
TRM-15-Input Input circuit
TRM-15-SUPP Vehicle ignition supply
TRM-30A Power supply terminal
TRM-30A-GNDB Ground
TRM-30B Power supply terminal
TRM-30B-GNDB Ground
1 Brake system
2 Motor vehicle
3 Trailer brake
4 Trailer vehicle
Holding brake module
6 Control valve
7 Redundancy valve
8 Shuttle valve
9 Compressed-air supply
10 First compressed-air tank
11 Second compressed-air tank
12 Third compressed-air tank
13 Wheel
14 Holding brake valve
Pressure sensor
16 Electronic control unit of the brake system
17 CAN bus
18 Electronic control unit of the motor vehicle
19 Man-machine interface
20 First electronic control line
21 Second electronic control line
22 Electronic circuit
23 Housing of the electronic control unit of the brake system
24 Safety control unit
25 Inverter
26 Locking unit
27 First delay unit
28 First memory unit
29 Redundancy logic system
30 Inverter of the redundancy logic system
31 First OR-gate
32 First normal-operation control signal
33 Status signal
34 Inverted status signal
35 Second normal-operation control signal
36 Output signal of the first delay unit
37 Signal input of the first memory unit
38 Triggering connection of the first memory unit
39 Reset connection of the first memory unit
40 Triggering signal
41 Rising flank of the inverted status signal
42 First failsafe control signal
43 Signal output of the first memory unit
44 Second OR-gate
45 Third OR-gate
46 Output signal to the Low-side switch
47 First input of the second OR-gate
48 Second input of the second OR-gate
49 Output of the second memory unit
50 Second memory unit
51 Second delay unit
52 Third normal-operation control signal
53 Time-delayed second normal-operation control, signal
54 Second failsafe control signal
55 Chosen failsafe control signal
56 First input of the third OR-gate
57 Second input of the third OR-gate
58 Output of the third OR-gate
59 Reset signal
60 Watchdog
61 Power supply unit
62 Reverse polarity protection
63 Reset unit
64 Limiter unit

1. An electronic circuit (22) comprising:
an electronic control unit (16);
a safety control unit (24); and
an electronic locking unit (26) with a delay unit (27) and with a memory unit (28); wherein:
the electronic control unit (16) is configured to control at least one actuator (7) by means of a normal-operation control signal (32) in a specified manner, and to generate a triggering signal (40) for the electronic locking unit (26) without the electronic control unit (16) having any influence on the generation of the triggering signal (40),
the delay unit (27) is configured to receive the normal-operation control signal (32), and to transmit the normal-operation control signal (32) to the memory unit (28) with a time delay,
the memory unit (28) is configured to receive the triggering signal (40) generated by the safety control unit (24), and to store the normal-operation control signal (36) transmitted by the delay unit (27) with the time delay, as soon as the memory unit (28) receives the triggering signal (40),
and
the electronic locking unit (26) is configured to control the actuator (7) on the basis of the stored normal-operation control signal (36) as the output signal (42) of the memory unit (28), as soon as the memory unit (28) has received the triggering signal (40) and has stored the normal-operation control signal (36) transmitted with the time delay.

2. The electronic circuit (22) according to claim 1, wherein:
the electronic control unit (16) is configured to control a high-side switch (HSS) of the actuator (7) by means of the normal-operation control signal (32) in the specified manner, and
the electronic locking unit (26) is configured to control a low-side switch (LSS) of the actuator (7) by means of the stored normal-operation control signal (36).

3. The electronic circuit (22) according to claim 2, wherein the electronic control unit (16) is configured to control the low-side switch (LSS) of the actuator by pulse width modulation.

4. The electronic circuit (22) according to claim 1, wherein:
the safety control unit (24) is configured to generate a status signal which has either a normal-operation value (“1”) or a fault value (“0”),
the normal-operation value (“1”) indicates that the actuator (7) is being controlled in the specified manner,
the fault value (“0”) indicates that the actuator (7) is not being controlled in the specified manner,
the safety control unit (24) comprises an inverter (25), and
the inverter (25) is configured to convert the fault value (“0”) to the normal-operation value (“1”) and to transmit this normal-operation value (“1”) as the triggering signal (40) to the memory unit (28).

5. The electronic circuit (22) according to claim 4, wherein
the memory unit (28) is configured to receive a reset signal (59),
the locking unit (26) is configured to control the actuator (7) by means of the stored normal-operation control signal (36) only until the memory unit (28) receives the reset signal (59), and
the electronic control unit (16) is configured to take over the control of the actuator (7) again as soon as the memory unit (28) receives the reset signal (59).

6. The electronic circuit (22) according to claim 5, wherein the reset signal (59) is generated by a reset unit (63) separate from the locking unit (26).

7. The electronic circuit (22) according to claim 6, wherein the inverter (25) is configured to convert the normal-operation value (“1”) to the fault value (“0”) and to transmit this fault value (“0”) as the reset signal (59) to the memory unit (28).

8. The electronic circuit (22) according to claim 4, wherein:
the fault value (“0”) indicates that the actuator (7) is not being controlled by the electronic control unit (16) in the specified manner by means of the normal-operation control signal (32), because the electronic control unit (16) is in a starting phase, and
the electronic control unit (16) is configured
to measure analog return-messages of the high-side switch (HSS) and the low-side switch (LSS) of the actuator (7) and as a function thereof to infer an operating condition of the locking unit (26) while the electronic control unit (16) is in the starting phase, and the safety control unit (24) has generated the status signal (33) in such manner that it adopts the fault value (“0”), and
to control the actuator (7) on the basis of the measured return-messages in such manner that the locking unit (26) maintains its operating condition after the electronic control unit (16) has finished its start phase.

9. The electronic circuit (22) according to claim 1, wherein the safety control unit (24) comprises a watchdog (60) connected on the input side to the electronic control unit (16) and on the output side to the inverter (25).

10. The electronic circuit (22) according to claim 1, wherein the delay unit (24) is configured to transmit the normal-operation control signal (32) to the memory unit (28) with a time delay of at least 25 milliseconds.

11. A brake system (1) for a motor vehicle (2), the brake system (1) comprising:
an electronically controlled parking brake module (5) with
a first directional valve in the form of a control valve (6),
a second directional valve in the form of a redundancy valve (7), and
a pressure-controlled shuttle valve (8),
an electronic circuit (22) according to claim 1, wherein:
the electronic control unit (16) of the electronic circuit (22) is configured to control the redundancy valve (7) as an actuator by means of a normal-operation control signal (32) in a specified manner,
the safety control unity (24) of the electronic circuit (22) is designed to generate the triggering signal (40) for the electronic locking unit (26), without the electronic control unit (16) having any influence on the generation of the triggering signal (40),
the delay unit (27) of the locking unit (26) of the electronic circuit (22) is configured to receive the normal-operation control signal (32), and to transmit the normal-operation control signal (32) to the memory unit (28) of the electronic circuit (22) with the time delay,
the memory unit (28) is configured to receive the triggering signal (40) generated by the safety control unit (24), and to store normal-operation control signal (36) transmitted by the delay unit (27) with the time delay, as soon as the memory unit (28) receives the triggering signal (40),
and
the electronic locking unit (26) of the electronic circuit (22) is configured to control the redundancy valve (7) by means of the stored normal-operation control signal (36) as the output signal (42) of the memory unit (28), as soon as the memory unit (28) receives the triggering signal (40) and has stored the normal-operation control signal (36).

12. The brake system (1) according to claim 11, further comprising a further delay unit (51) and a further memory unit (50), wherein:
the electronic control unit (16) is configured to control the control valve (6) as a further actuator by means of a further normal-operation control signal (52), in a specified manner,
the further delay unit (51) is configured to receive the further normal-operation control signal (52), and to transmit the further normal-operation control signal (52) with the time delay to the further memory unit (50),
the further memory unit (50) is configured to receive the triggering signal (40) generated by the safety control unit (24), and to store the further normal-operation control signal (53) transmitted with the time delay by the further delay unit (51), as soon as the further memory unit (50) receives the triggering signal (40), and
the electronic locking unit (26) is configured to control the control valve (7) by means of the stored normal-operation control signal (53) as the output signal of the further memory unit (50), as soon as the further memory unit (50) has received the triggering signal (40), and has stored the further normal-operation control signal (53).
